(19) United States
(12) Patent Application Publication
(10) Pub. No.: US 2023/0413437 A1
(43) Pub. Date: Dec. 21, 2023

(54) PRINTED CIRCUIT BOARD

(71) Applicant: SAMSUNG ELECTRO-MECHANICS CO., LTD., Suwon-si (KR)

(72) Inventor: Kye Hwan LEE, Suwon-si, Gyeonggi-do (KR)

(73) Assignee: SAMSUNG ELECTRO-MECHANICS CO., LTD., Suwon-si (KR)

(21) Appl. No.: 17/939,081

(22) Filed: Sep. 7, 2022

(30) Foreign Application Priority Data
Jun. 16, 2022 (KR) 1020220073660

(51) Int. Cl. H05K 1/11; H05K 1/09; H05K 3/46

(52) U.S. Cl. CPC H05K 1/113; H05K 1/09; H05K 3/4644

(57) ABSTRACT

A printed circuit board includes a first insulating layer, a first pad embedded in one surface side of the first insulating layer and having one surface exposed from one surface of the first insulating layer, and a first surface treatment layer disposed on the exposed one surface of the first pad. A boundary surface between the first pad and the first surface treatment layer is substantially coplanar with the one surface of the first insulating layer.

### CROSS-REFERENCE TO RELATED APPLICATIONS

This application claims benefit of priority to Korean Patent Application No. 10-2022-0073660 filed on Jun. 16, 2022 in the Korean Intellectual Property Office, the disclosure of which is incorporated herein by reference in its entirety.

### TECHNICAL FIELD

The present disclosure relates to a printed circuit board.

### BACKGROUND

To respond to the recent trend for lightweight, miniaturized mobile devices, it may also be necessary to reduce the weight, a thickness, and a size of a printed circuit board mounted thereon. In response to technical demands in relation to reductions in weight, thickness, and size of mobile devices, studies has been continuously conducted to reduce a thickness of a substrate in a substrate structure on which various components are mounted and to improve reliability when components are connected to a substrate.

### SUMMARY

An aspect of the present disclosure is to provide a printed circuit board having a reduced thickness.

Another aspect of the present disclosure is to provide a method of manufacturing a printed circuit board which may improve reliability.

Another aspect of the present disclosure is to provide a printed circuit board which may reduce manufacturing costs by reducing a thickness of a surface treatment layer.

According to an aspect of the present disclosure, a printed circuit board includes a first insulating layer, a first pad embedded in one surface side of the first insulating layer and having one surface exposed from one surface of the first insulating layer, and a first surface treatment layer disposed on the exposed one surface of the first pad. A boundary surface between the first pad and the first surface treatment layer is substantially coplanar with the one surface of the first insulating layer.

According to an aspect of the present disclosure, a printed circuit board includes a first pad embedded in one surface side of the first insulating layer and having one surface exposed from one surface of the first insulating layer, and a second pad embedded in the one surface side of the first insulating layer and having one surface exposed from the one surface of the first insulating layer. The one surface of the second pad and the one surface of the first insulating layer have a step difference therebetween.

According to an aspect of the present disclosure, a printed circuit board includes an insulating layer, a pad embedded in the insulating layer, and having one surface exposed from one surface of the insulating layer and substantially coplanar with the one surface of the insulating layer, and a first solder resist layer disposed on the one surface of the insulating layer, and having an opening exposing a region of the insulating layer where the pad is embedded.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a perspective diagram illustrating an example of an electronic device;

FIG. 3 is a cross-sectional diagram illustrating an example of a printed circuit board;

FIG. 4 is a cross-sectional diagram illustrating another example embodiment of a printed circuit board;

FIG. 5 is a cross-sectional diagram illustrating another example embodiment of a printed circuit board;

FIGS. 6 to 8 are diagrams illustrating processes of a method of manufacturing the printed circuit board illustrated in FIG. 3;

FIGS. 9 to 11 are diagrams illustrating processes of a method of manufacturing the printed circuit board illustrated in FIG. 4; and

FIGS. 12 to 14 are diagrams illustrating processes of a method of manufacturing the printed circuit board illustrated in FIG. 5.

### DETAILED DESCRIPTION

Hereinafter, embodiments of the present disclosure will be described as follows with reference to the attached drawings.

Electronic Device

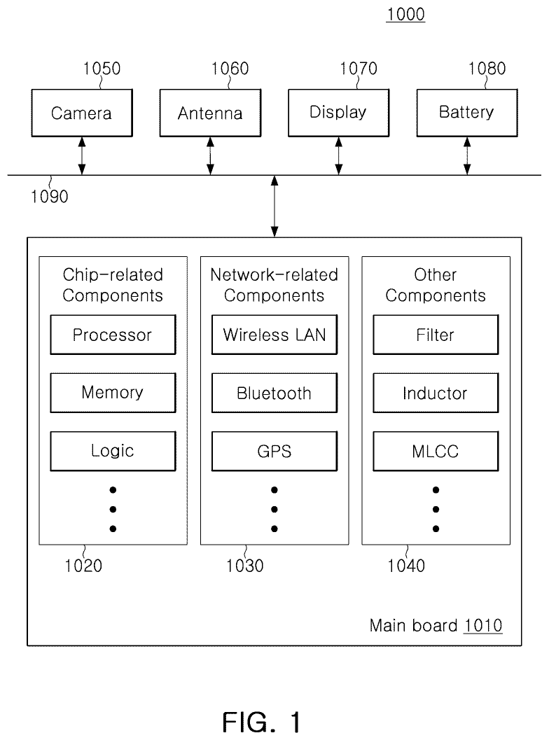

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. Also, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. The other components may include, for example, a camera module 1050, an antenna 1060, a display device 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

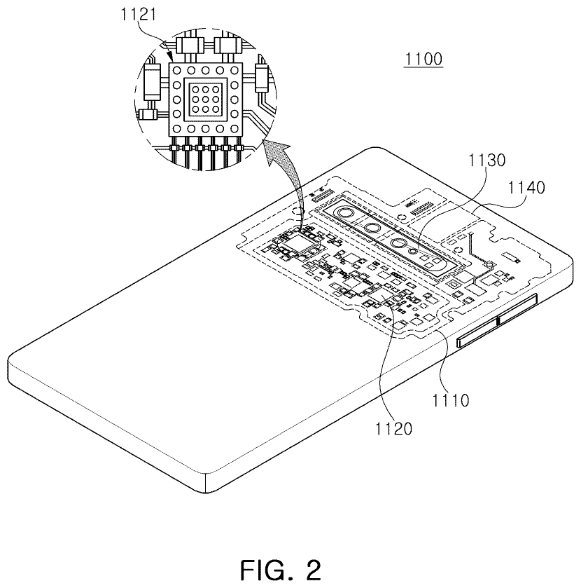

FIG. 2 is a perspective diagram illustrating an example of an electronic device.

Referring to FIG. 2, the electronic device may be, for example, a smartphone 1100. For example, a motherboard 1110 may be accommodated in the smartphone 1100, and various electronic components 1120 may be physically or electrically connected to the motherboard 1110. Also, other components which may or may not be physically or electrically connected to the motherboard 1110, such as a camera module 1130 and/or a speaker 1140, may be accommodated in the body 1101. A portion of the electronic components 1120 may be the chip related components, a component package 1121, for example, but are not limited thereto. The component package 1121 may be in the form of a printed circuit board on which electronic components including active components and/or passive components are surface-mounted. Alternatively, the component package 1121 may be in the form of a printed circuit board in which active components and/or passive components are embedded. The electronic device is not necessarily limited to the smartphone 1100, but may be other electronic devices as described above.

Printed Circuit Board

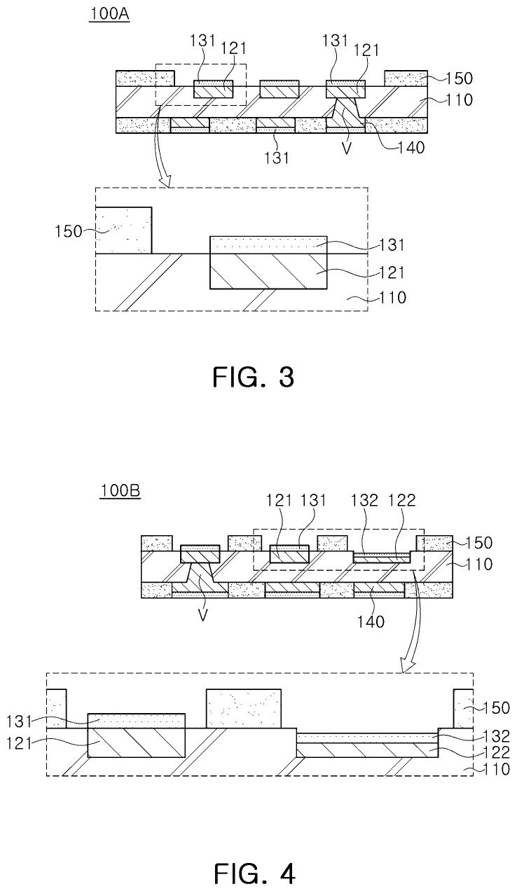

FIG. 3 is a cross-sectional diagram illustrating an example of a printed circuit board

Referring to the drawings, a printed circuit board 100A according to an example embodiment may include a first insulating layer 110, a first pad 121 embedded in one surface side of the first insulating layer 110, and having one surface exposed from one surface of the first insulating layer 110, and a first surface treatment layer 131 disposed on one surface of the first pad 121.

The first insulating layer 110 may include an insulating material. The insulating material may include a thermosetting resin such as epoxy resin, a thermoplastic resin such as polyimide, or a material including an inorganic filler, an organic filler and/or a glass fibers (glass cloth, and/or glass fabric) together with the above-mentioned resins. The insulating material may be a photosensitive material and/or a non-photosensitive material. For example, as an insulating material, solder resist (SR), Ajinomoto build-up film (ABF), FR-4, bismaleimide triazine (BT), prepreg (PPG), resin coated copper (RCC) insulating material, copper clad laminate (CCL) may be used, but an example embodiment thereof is not limited thereto, and other polymeric materials may be used.

The first pad 121 may have a structure embedded in the first insulating layer 110. That is, the first pad 121 may be embedded in one surface side of the first insulating layer 110, one surface of the first pad 121 may be exposed to one surface of the first insulating layer 110, and the other surface other than the one surface of the first pad 121 may be in contact with and covered by the first insulating layer 110, but the other surface may not be covered by being in physically in contact with the first insulating layer 110, and the other surface may be embedded in the first insulating layer 110 by a portion thereof being spaced apart therefrom. Since the first pad 121 has a structure embedded in the first insulating layer 110 rather than a protruding pattern, an insulating layer of a build-up layer may be reduced by embedding an outermost layer of the build-up layer, such that a thickness of the entirety of the printed circuit board may be reduced.

Also, one surface of the first pad 121 may be substantially coplanar with one surface of the first insulating layer 110, but an example embodiment thereof is not limited thereto. The notion that two surfaces are coplanar with each other may indicate that two surfaces are coplanar with each other without a step difference. The notion that the surfaces are substantially coplanar with each other may alternatively indicate that the surfaces are almost coplanar with each other, and may include errors in the manufacturing process. When the process of removing the carrier substrate C is performed, which will be described in the manufacturing process later, the first pad 121 may be protected from being etched by the barrier layer B such that one surface of the first pad may be coplanar with one surface of the first insulating layer 110.

The first pad 121 may include a metal material. A metal material may include copper (Cu), aluminum (Al), silver (Ag), tin (Sn), gold (Au), nickel (Ni), lead (Pb), titanium (Ti), and/or alloys thereof, and may include copper (Cu) preferably, but an example embodiment thereof is not limited thereto. The first pad 121 may perform various functions according to a design. For example, the first pad 121 may include a ground pad, a power pad, and a signal pad. Here, the signal pad may include a pad for electrical connection of various signals other than ground and power, such as, for example, a data signal. The first pad may be formed by one of a semi-additive process (SAP), a modified semi-additive process (MSAP), and a subtractive method, but an example embodiment thereof is not limited thereto.

The first pad 121 may include a plurality of pads. The plurality of pads may be simultaneously formed in the process of forming the first pad 121, and may have the characteristics of the first pad 121 described above. Also, the first pad 121 may electrically transmit signals to and receive signals from different pads and/or circuits, and may perform a function by being electrically short-circuited with other pads.

Meanwhile, although not illustrated in the drawings, an electronic component may be mounted on one surface of the first pad 121, and the electronic component may be a generally used active component or a passive component. The electronic component may have a connection electrode for connection to the printed circuit board, and the connection electrode may be electrically connected to the first pad 121 through metal wire bonding. The metal wire bonding may be connected to the first pad 121 through a first surface treatment layer 131 described later.

The first surface treatment layer 131 may be formed on one surface of the first pad 121. The first surface treatment layer 131 is formed to cover one surface of the first pad 121.

The first surface treatment layer 131 may perform a function of preventing oxidation or contamination of the surface of the first pad 121 and allowing a wire or solder to be closely coupled to the first pad 121. For example, the first surface treatment layer 131 may include one of gold (Au) and nickel (Ni), and a plurality of the metal layers may be provided. That is, the first surface treatment layer 131 may be implemented by gold plating, and if desired, the first surface treatment layer 131 may be implemented by nickel plating. Furthermore, a gold plating layer and a nickel plating layer may be formed in sequence on one surface of the first pad 121 and may form the first surface treatment layer 131, and the first surface treatment layer 131 may be implemented by an alloy including at least one of nickel and gold. The first surface treatment layer 131 may be formed through electroplating or electroless plating.

Meanwhile, the first surface treatment layer 131 according to an example embodiment may be formed on one surface of the first pad 121 and may be formed on a level higher than a level of one surface of the first insulating layer 110, and the first surface treatment layer 131 may be exposed. The width of the first surface treatment layer 131 may be configured to be the same as the width of the first pad 121, such that the side surface of the first surface treatment layer 131 may be coplanar with the side surface of the first pad 121, but an example embodiment thereof is not limited thereto. The width of the first surface treatment layer 131 may be greater than the width of the first pad 121, and in this case, the component may be formed on a portion of one surface of the first insulating layer 110.

The boundary surface between the first surface treatment layer 131 and the first pad 121 may be coplanar with one surface of the first insulating layer 110, but an example embodiment thereof is not limited thereto, which may be related to the arrangement of one surface of the first pad 121, and when one surface of the first pad 121 is coplanar with one surface of the first insulating layer 110, the boundary surface between the first surface treatment layer 131 and the first pad 121 may be coplanar with one surface of the first insulating layer 110. Since etching of the first pad 121 is reduced by the barrier layer B in a manufacturing process described later, the first pad 121 may remain to the maximum. As the first pad 121 is not etched, even when a thickness of the first surface treatment layer 131 disposed on the first pad 121 is reduced, wire bonding for mounting an electronic component may be performed. That is, the component mounting region may be formed while reducing the first surface treatment layer 131. Accordingly, the cost of forming the first surface treatment layer may be reduced, and by reducing the space for controlling the thickness of the surface treatment layer, a fine circuit pattern and a component mounting pad may be implemented.

Meanwhile, as the first pad 121 includes a plurality of pads, the first surface treatment layer 131 may also include a plurality of surface treatment layers.

A circuit pattern 140 may be further included on the other surface opposite to one surface of the first insulating layer 110. The circuit pattern 140 may refer to a generally used circuit for a printed circuit board, and in some cases, the circuit pattern 140 may perform the same function as that of the first pad 121. The circuit pattern 140 may be formed through electroless plating or electrolytic plating, and the circuit pattern may include a seed layer, but an example embodiment thereof is not limited thereto, and the circuit pattern may be integrally formed with the seed layer. The circuit pattern may be formed by one of generally used methods for forming a pattern. Also, the circuit pattern 140 may be electrically connected to the other components on the other surface of the first insulating layer 110, and a portion of the circuit pattern 140 may be electrically connected to the first pad 121 through a via V penetrating the first insulating layer 110. The via V may be formed by a generally used method used by a person skilled in the art.

Meanwhile, the first surface treatment layer 131 may also be disposed on one surface of the circuit pattern 140 disposed on the other surface of the first insulating layer 110. When the circuit pattern 140 functions as a pad on the other surface of the first insulating layer 110, the first surface treatment layer 131 may be disposed on one surface of the circuit pattern 140, but an example embodiment thereof is not limited thereto.

A solder resist layer 150 may be further disposed on one surface of the first insulating layer 110. The solder resist layer 150 may protect the printed circuit board 100A from the outside. The solder resist layer 150 may include a thermosetting resin and an inorganic filler dispersed in the thermosetting resin, and may not include glass fiber. The insulating resin may be a photosensitive insulating resin, and the filler may be an inorganic filler and/or an organic filler, but an example embodiment thereof is not limited thereto. However, the material of the solder resist layer 150 is not limited thereto, and other polymer materials may be used if desired.

The solder resist layer 150 may include an opening, and the first pad 121 and the first surface treatment layer 131 may be exposed through the opening. When the first pad 121 and the first surface treatment layer 131 include a plurality of pads and a plurality of surface treatment layers, respectively, the solder resist layer 150 may expose the plurality of first pads 121 and the plurality of first surface treatment layers 131 through the opening, but an example embodiment thereof is not limited thereto, and solder resist layer 150 may expose a portion of the plurality of components.

The printed circuit board 100A according to an example embodiment is not limited to the configuration illustrated in the drawings, and may further include generally used components of a printed circuit boards including another insulating layer, another circuit pattern, a through via and a cavity. That is, the printed circuit board 100A may further include a component used by a person skilled in the relevant technical field.

FIG. 4 is a cross-sectional diagram illustrating another example embodiment of a printed circuit board.

In the printed circuit board 100B according to another example embodiment, a second pad 122 and a second surface treatment layer 132 may be disposed one surface of the first insulating layer 110 in addition to the first pad 121 and the first surface treatment layer 131.

The second pad 122 may have a structure embedded in the first insulating layer 110. That is, one surface of the second pad 122 may be exposed to one surface of the first insulating layer 110, and the other surface other than the one surface of the second pad 122 may be covered by being in contact with the first insulating layer 110. However, the surface is not covered by being physically in contact and may be embedded in the first insulating layer 110 while being partially spaced.

One surface of the second pad 122 may have a step difference from the one surface of the first insulating layer 110. The configuration in which the surfaces have a step difference may indicate that the surfaces are not coplanar with each other. As described later in the manufacturing process, when the second pad 122 is formed in a region in which the barrier layer B is not present, and the second metal layer C2 of the carrier substrate C is removed, a portion of the second pad 122 is etched together, such that one surface of the second pad 122 is formed on a level lower than a level of one surface of the first insulating layer 110 and a step difference may be formed. Since one surface of the second pad 122 is formed to be lower than one surface of the first insulating layer 110, a portion of the side surface of the first insulating layer 110 may be exposed.

The second pad 122 may be formed simultaneously with the first pad 121, and may be formed of the same material as that of the first pad, or may be formed through another step.

Meanwhile, although not illustrated in the drawings, an electronic component may be mounted on one surface of the second pad 122, and the electronic component may be a generally used active component or a passive component. The electronic component may have a connection electrode for connection to the printed circuit board, and the connection electrode may be electrically connected to the second pad 122 through a solder ball. A connection means such as a solder ball may be connected to the second pad 122 through a second surface treatment layer 132 described later.

The second surface treatment layer 132 may be formed on one surface of the second pad 122. The second surface treatment layer 132 may cover one surface of the second pad 122.

The second surface treatment layer 132 may perform a function of preventing oxidation or contamination of the surface of the second pad 122, and allowing a wire or solder to be closely coupled to the second pad 122. The second surface treatment layer 132 may include an organic material, but an example embodiment thereof is not limited thereto. When an organic material is included, the second surface treatment layer 132 may be formed by a generally used organic solderability preservative (OSP) organic layer coating, but an example embodiment thereof is not limited thereto, and any material used by a person skilled in the art may be used. As the second surface treatment layer 132 is formed on one surface of the second pad 122, reliability of the coupling between the second pad 122 and a connection means such as a solder ball may improve.

The second surface treatment layer 132 may have a reduced thickness, such that the second surface treatment layer 132 may be embedded in the first insulating layer 110. One surface of the second surface treatment layer 132 may be formed on a level lower than a level of one surface of the first insulating layer 110, such that one surface of the second surface treatment layer 132 may have a step difference from one surface of the first insulating layer 110. Also, the width of the second surface treatment layer 132 may be the same as the width of the second pad 122, such that the side surface of the second surface treatment layer 132 may be coplanar with the side surface of the second pad 122 and may be covered by the first insulating layer 110.

Among the components other than the second pad 122 and the second surface treatment layer 132, the same components as those of the printed circuit board 100A according to an example embodiment may be applied to the printed circuit board 100B according to another example embodiment, and thus, overlapping description thereof will not be provided.

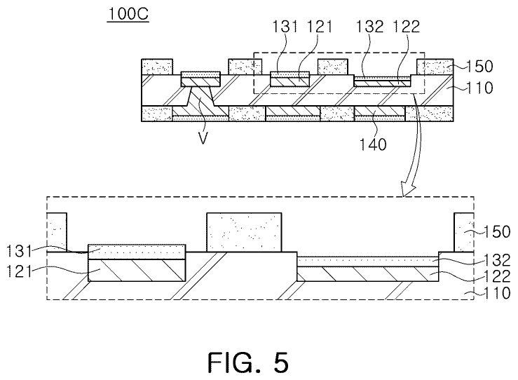

FIG. 5 is a cross-sectional diagram illustrating another example embodiment of a printed circuit board.

In a printed circuit board 100C according to another example embodiment, a second pad 122 and a second surface treatment layer 132 may be disposed on one surface of the first insulating layer 110 in addition to the first pad 121 and the first surface treatment layer 131, and one surface of the first pad 121 may not be coplanar with one surface of the first insulating layer 110.

The first pad 121 of the printed circuit board 100C according to another example embodiment may be embedded in the first insulating layer 110, but one surface of the first pad 121 may have a step difference with one surface of the first insulating layer 110, which may be because, in the manufacturing process, only the barrier layer B is formed only in the region corresponding to the first pad 121, such that, in the process of forming the first insulating layer 110, one surface of the barrier layer B may be coplanar with one surface of the insulating layer, and when the barrier layer B is removed in a subsequent process, a step difference equal to the thickness in which the barrier layer B is present may be formed.

The first surface treatment layer 131 of the printed circuit board 100C according to another example embodiment may be formed on one surface of the first pad 121, and the first surface treatment layer 131 may protrude to one surface of the first insulating layer 110, but an example embodiment thereof is not limited thereto. When the first surface treatment layer 131 protrudes, one surface of the first surface treatment layer 131 may be disposed on a level higher than a level of one surface of the first insulating layer 110 and may have a step difference. Since the first surface treatment layer 131 protrudes such that one surface of the first surface treatment layer 131 is disposed on a level higher than a level of the one surface of the first insulating layer 110, at least a portion of the side surface of the first surface treatment layer 131 may be exposed

One surface of the first surface treatment layer 131 may be coplanar with one surface of the first insulating layer 110, which may be obtained by forming the first surface treatment layer 131 to have a thickness the same as the thickness of the barrier layer B in the region from which the barrier layer B is removed in the manufacturing process described later.

The width of the first surface treatment layer 131 may be the same as the width of the first pad 121, but an example embodiment thereof is not limited thereto. When the width of the first surface treatment layer 131 is the same as the width of the first pad 121, the side surface of the first surface treatment layer 131 may be coplanar with the side surface of the first pad 121. When the width of the first surface treatment layer 131 is formed to be wider than the width of the first pad 121, at least a portion of the first surface treatment layer may be formed to cover the first insulating layer 110.

In addition to the arrangement of the first pad 121 and the first surface treatment layer 131, the same components as those of the printed circuit board 100A according to one example embodiment and the printed circuit board 100B according to another example embodiment may also be applied to the printed circuit board 100C according to another example embodiment, and thus, overlapping description thereof will not be provided

Method of Manufacturing a Printed Circuit Board

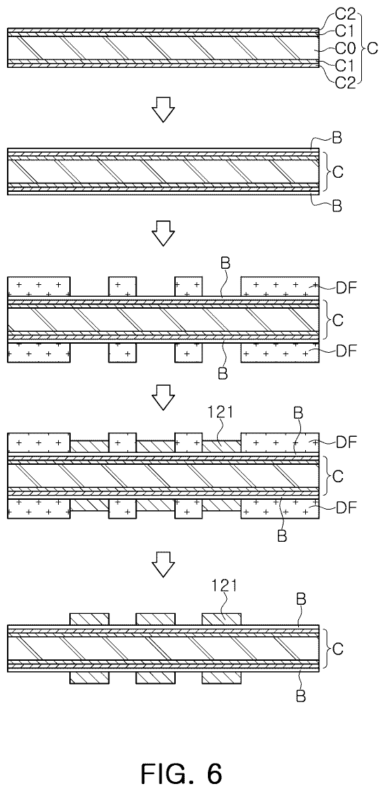

FIGS. 6 to 8 are diagrams illustrating processes of a method of manufacturing the printed circuit board illustrated in FIG. 3.

Referring to FIG. 6, a carrier substrate C including a core C0 and a first metal layer C1 and a second metal layer C2 formed in sequence on one or both surfaces thereof may be prepared.

The core C0 may be configured to support an insulating layer and/or a circuit layer when forming the insulating layer and/or the circuit layer, and the core C0 may be formed of an insulating material or a metal material. The first metal layer C1 may be formed of copper, but an example embodiment thereof is not limited thereto. The second metal layer C2 may function as a seed layer and may be formed of copper. In some cases, the first metal layer C1 and the second metal layer may be integrated with each other and may form a single metal layer.

However, the above-described carrier substrate C is merely an example, and as the carrier member, a member used by a person skilled in the art and used as a support substrate and detached or removed later may be used without limitation.

Thereafter, a barrier layer B may be formed on one surface of the second metal layer. The barrier layer B may work as an etching barrier of the first pad 121 in the process of removing the carrier substrate C, which will be described later.

The barrier layer B may be a metal layer including nickel (Ni), but an example embodiment thereof is not limited thereto, and a material different from that of the second metal layer C2 of the carrier substrate and/or the first pad 121 formed thereafter may be used, and the material may be used without limitations as long as the first pad 121 may work as a protective film to be etched in the process of removing the second metal layer C2.

Thereafter, the first pad may be formed by exposing and developing the dry film DF and removing the dry film DF after copper plating. The process of forming the first pad 121 is not limited thereto, and any process by which a generally used pad or conductor pattern may be formed may be used. That is, the first pad 121 may be formed by one of a semi additive process (SAP), a modified semi additive process (MSAP), or a subtractive method. In this case, the second metal layer may work as a seed layer.

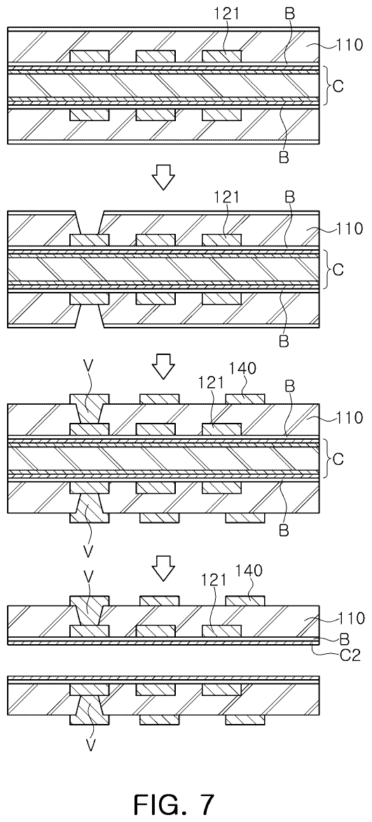

Referring to FIG. 7, after the manufacturing process illustrated in FIG. 6, the first insulating layer 110 may be formed to embed the first pad 121. The first insulating layer 110 may further include a seed layer on the other surface opposite to the one surface. The first insulating layer 110 may be the same as described in the example embodiment of the printed circuit board, and the first pad 121 may be embedded such that one surface of the first pad 121 may be exposed to one surface of the first insulating layer 110.

Thereafter, a through hole penetrating the first insulating layer may be formed, a circuit pattern 140 may be formed on the other surface of the first insulating layer, and a via V connecting the circuit pattern 140 to the first pad 121 may be formed. The circuit pattern 140 and the vias V may be formed through electroplating after forming the electroless copper plating seed layer as illustrated, but an example embodiment thereof is not limited thereto.

Thereafter, the carrier substrate C may be removed. The removing the carrier substrate C may be performed by firstly removing the core C0 and the first metal layer C1, and removing the second metal layer C2, but an example embodiment thereof is not limited thereto, and the core C0, the first metal layer C1 and the second metal layer C2 may be removed in sequence or may be collectively removed. However, in the example embodiment, the removing the core C0 and the first metal layer C1 is illustrated to more clearly describe the removing the second metal layer C2.

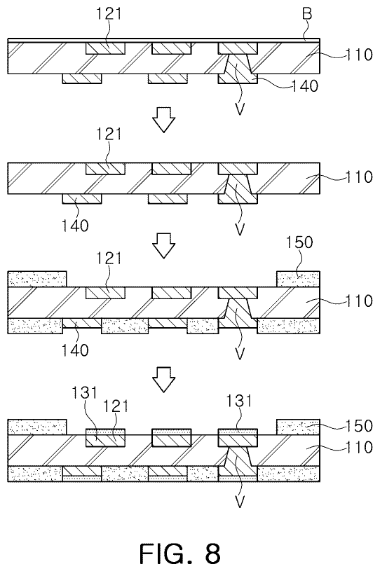

Referring to FIG. 8, after the manufacturing process described in FIG. 7, the second metal layer C2 may be removed. The second metal layer C2 may be removed by etching, and as described above, as the barrier layer B is formed of a different metal from that of the second metal layer C2, the first pad 121 may be prevented from being etched off in the process of etching the second metal layer C2. Since the barrier layer B protects the first pad 121, one surface of the first pad 121 may be coplanar with one surface of the first insulating layer 110, and the printed circuit board 100A according to the example embodiment may have improved signal connection and reliability.

Thereafter, a solder resist layer 150 may be formed on one surface and the other surface of the first insulating layer 110. The solder resist layer 150 may be formed only on one surface of the first insulating layer 110. The solder resist layer 150 may have an opening and the first pad 121 and the circuit pattern 140 may be exposed through the opening.

As described above, general components of a printed circuit board such as another insulating layer, another circuit pattern, a through via, and a cavity may be further formed on the other surface of the first insulating layer 110. That is, components which may be used by a person skilled in the art may be added if desired.

Thereafter, a first surface treatment layer 131 may be formed on one surface of the first pad 121. Since one surface of the first pad 121 is coplanar with one surface of the first insulating layer 110, the first surface treatment layer 131 may be formed on a level higher than a level of one surface of the first pad 121 and one surface of the first insulating layer 110. As described above, since the first pad 121 is protected by the barrier layer B of the second metal layer C2, the first pad 121 may not be removed and the first surface treatment layer 131 may be reduced.

Meanwhile, the first surface treatment layer 131 may also be formed on the circuit pattern 140 formed on the other surface of the first insulating layer 110. Also, as described above, when another insulating layer is added to the other surface of the first insulating layer 110, a surface treatment layer may be further included in the circuit pattern disposed on an outermost layer, but an example embodiment thereof is not limited thereto.

The printed circuit board 100A according to an example embodiment may be formed through a series of processes, but the manufacturing process is not necessarily limited thereto.

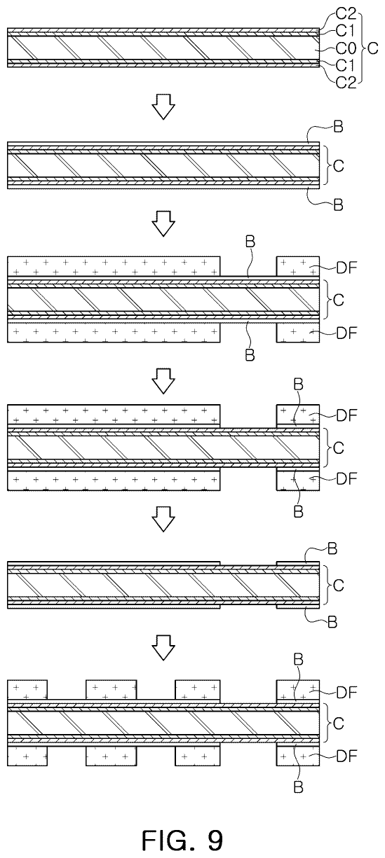

FIGS. 9 to 11 are diagrams illustrating processes of a method of manufacturing the printed circuit board 100B illustrated in FIG. 4.

Referring to FIG. 9, a process of forming the barrier layer B on the carrier substrate C and partially removing the barrier layer B may be included. A portion of the barrier layer B may be removed through the dry film DF on one surface of the barrier layer B, and accordingly, an opening may be formed in the region in which the second pad 122 is formed. In the process of removing the carrier substrate C through the opening, a portion of the second pad 122 may be removed together such that one surface of the second pad 122 may have a step difference from one surface of the first insulating layer 110. The removing the barrier layer B may be performed through an etching process, but an example embodiment thereof is not limited thereto, and a process by which the metal layer may be selectively removed may be used without limitation.

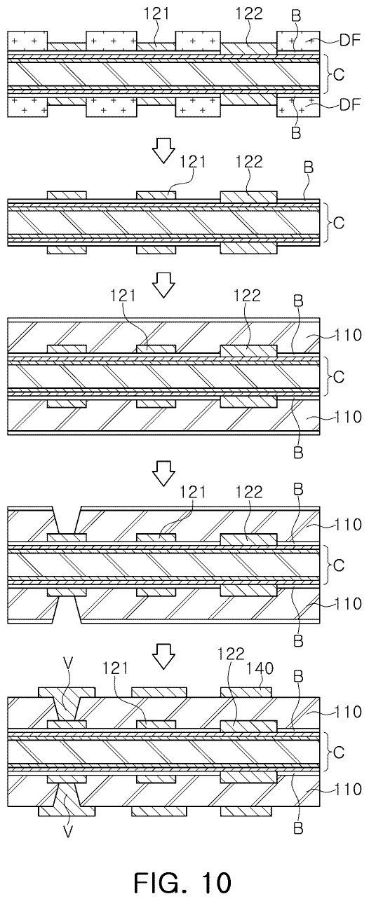

Referring to FIG. 10, a first pad 121 and a second pad 122 may be formed. The first pad 121 may be formed on the region from which the barrier layer B is not removed, that is, on one surface of the barrier layer B, and the second pad 122 may be formed on the region from which the barrier layer B is removed.

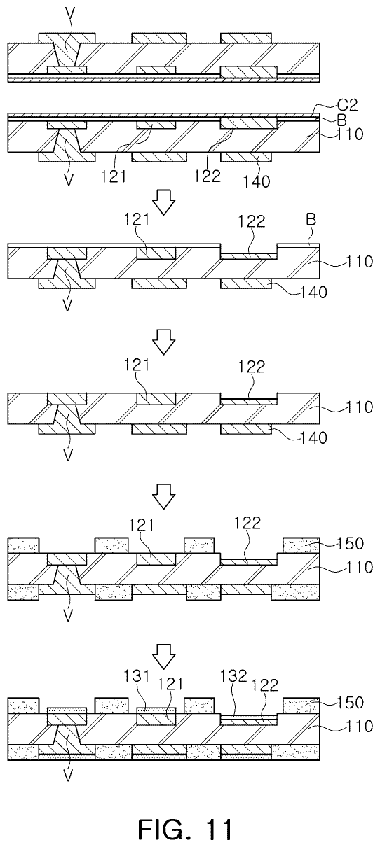

Referring to FIG. 11, the core C0 and the first metal layer C1 of the carrier substrate C may be removed, and the second metal layer C2 may be removed. In this case, since the second metal layer C2 is formed of the same material as that of the first and second pads 121 and 122, the second pad 122 may be removed together when the second metal layer C2 is removed. Also, since the barrier layer B is formed between the first pad 121 and the second metal layer C2, the first pad 121 may be protected. Accordingly, a portion of the second pad 122 may be removed, and the first pad 121 may be protected. Thereafter, the first and second pads 121 and 122 may be exposed by performing a process of removing the barrier layer B.

Thereafter, in the process of forming the first surface treatment layer 131 and the second surface treatment layer 132, the first surface treatment layer 131 and the second surface treatment layer 132 may be formed in sequence. The first surface treatment layer 131 may be formed, and thereafter, the second surface treatment layer 132 may be formed, but an example embodiment thereof is not limited thereto and the order may be changed. The second surface treatment layer 132 may be formed by a coating method, but an example embodiment thereof is not limited thereto, and any process by which a thin and uniform film may be formed may be used.

The other descriptions, that is, for example, the description in the above-described example embodiment of manufacturing the printed circuit board 100A may be applied to the other example embodiment of manufacturing of the printed circuit board 100B unless otherwise indicated, and overlapping descriptions will not be provided. Also, the example embodiment of manufacturing the printed circuit board 100A according to the above-described example may be similarly applied to the manufacturing of the printed circuit board 100B according to another example embodiment.

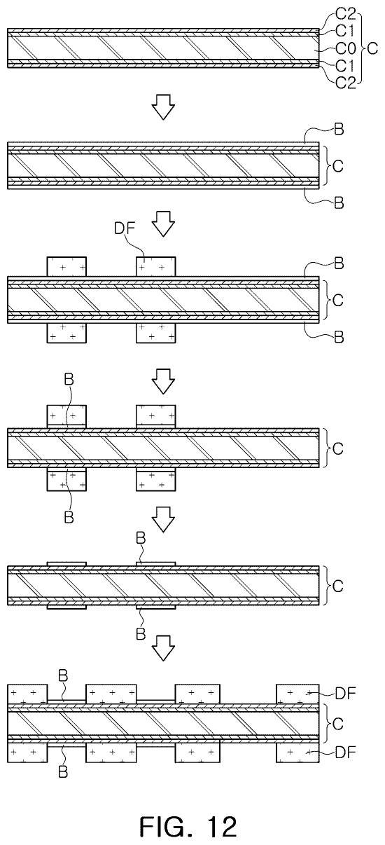

FIGS. 12 to 14 are diagrams illustrating processes of a method of manufacturing the printed circuit board 100C illustrated in FIG. 5.

Referring to FIG. 12, a process of forming the barrier layer B on the carrier substrate C and removing a portion of the barrier layer B may be included. Accordingly, the barrier layer B in the region other than the region in which the first pad 121 is formed may be removed.

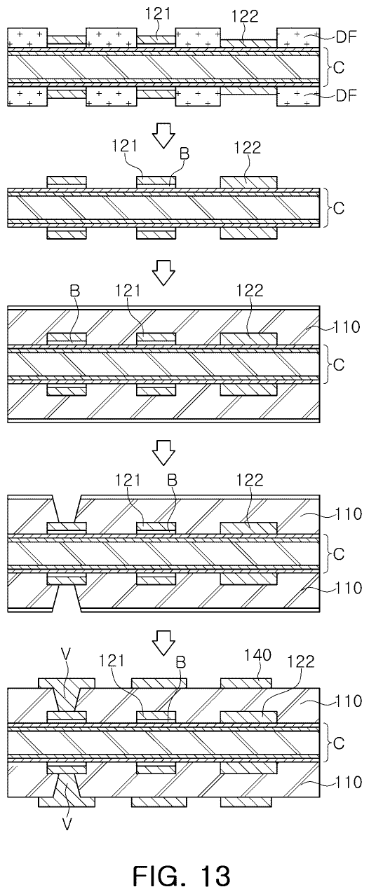

Referring to FIG. 13, when the first pad 121 and the second pad 122 are formed, the first pad 121 may be formed on one surface of the barrier layer B, and the second pad 122 may be formed in a portion of the region from which the barrier layer B is removed.

Thereafter, in the process of forming the first insulating layer 110, the first insulating layer 110 may be formed in a region from which the barrier layer B is removed, and the barrier layer B may be embedded together with the first and second pads 121 and 122.

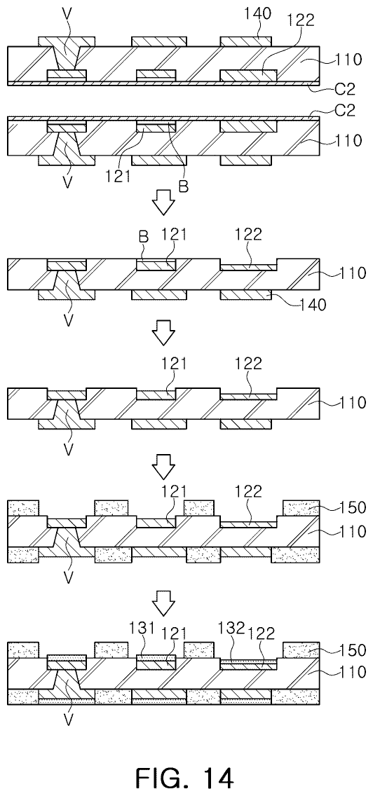

Referring to FIG. 14, the core C0 and the first metal layer C1 of the carrier substrate C may be removed, and the second metal layer C2 may be removed. In this case, since the second metal layer C2 is formed of the same material as that of the first and second pads 121 and 122, the second pad 122 may be removed together when the second metal layer C2 is removed. Also, since the barrier layer B is formed between the first pad 121 and the second metal layer C2, the first pad 121 may be protected. Accordingly, a portion of the second pad 122 may be removed, and the first pad 121 may be protected.

Thereafter, the barrier layer B disposed on one surface of the first pad 121 may be removed by performing the process of removing the barrier layer B. In the manufacturing method according to another example embodiment of the printed circuit board 100C, since the first insulating layer 110 is formed to fill the barrier layer B, a step difference may be formed between one surface of 110 and one surface of the first pad 121 by the thickness of the barrier layer B in the process of removing the barrier layer B. However, such a step difference may be smaller than a step difference between one surface of the first insulating layer 110 and one surface of the second pad 122 formed by removing the second pad 122 in the process of removing the second metal layer C2. That is, a greater number of pads may remain by protecting the pad in the process of removing the second metal layer C2 by forming the barrier layer B than by removing a portion of the pad without forming the barrier layer B.

Thereafter, the first surface treatment layer 131 and the second surface treatment layer 132 may be formed. The first surface treatment layer 131 may protrude to one surface of the first insulating layer 110, but an example embodiment thereof is not limited thereto.

The other descriptions, that is, for example, the description in the above-described example embodiment of manufacturing the printed circuit board 100A and the printed circuit board 100B according to another example embodiment may be applied to the other example embodiment of manufacturing of the printed circuit board 100C unless otherwise indicated, and overlapping description will not be provided. Also, the example embodiment of manufacturing the printed circuit board 100A according to the above-described example and another example embodiment of the printed circuit board 100B may be similarly applied to another example embodiment of manufacturing the printed circuit board 100C.

According to the aforementioned example embodiments, a printed circuit board having a reduced thickness may be provided.

Also, a printed circuit board which may improve reliability may be provided.

Also, a method for manufacturing a printed circuit board which may reduce costs may be provided.

In the example embodiment, the meaning on a cross-section may mean a cross-sectional shape when the object is vertically cut, or a cross-sectional shape when the object is viewed from a side-view. Also, the meaning on a plane may be a shape when the object is horizontally cut, or a planar shape when the object is viewed from a top-view or a bottom-view.

In the example embodiment, the upper side, the upper side, the upper surface, or the like, are used to refer to the direction toward the mounting surface on which the electronic component is mounted based on the cross-section of the drawing for convenience, and the lower side, the lower side, the lower surface, or the like, are used as the opposite directions. However, the direction is defined as above for ease of description, and the scope of the claims is not limited to any particular example by the descriptions of the directions.

In the example embodiments, the term “connected” may not only refer to “directly connected” but also include “indirectly connected” by may refer to of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as relevant to the other example embodiment unless otherwise indicated.

An expression used in the singular encompasses the expression of the plural, unless it has a clearly different meaning in the context.

While the example embodiments have been illustrated and described above, it will be apparent to a person skilled in the art that modifications and variations could be made without departing from the scope of the present disclosure as defined by the appended claims.

What is claimed is:

1. A printed circuit board, comprising:
a first insulating layer;
a first pad embedded in one surface side of the first insulating layer and having one surface exposed from one surface of the first insulating layer; and
a first surface treatment layer disposed on the exposed one surface of the first pad,
wherein a boundary surface between the first pad and the first surface treatment layer is substantially coplanar with the one surface of the first insulating layer.

2. The printed circuit board of claim 1, wherein the first surface treatment layer includes one of gold (Au) and nickel (Ni).

3. The printed circuit board of claim 1, further comprising:
a solder resist layer disposed on the one surface of the first insulating layer.

4. The printed circuit board of claim 3,
wherein the solder resist layer has an opening, and
wherein the first surface treatment layer is exposed through the opening.

5. The printed circuit board of claim 4,
wherein the first pad and the first surface treatment layer are provided as a plurality of first pads and a plurality of first surface treatment layers, respectively, and
wherein the opening of the solder resist layer exposes the plurality of first pads and the plurality of first surface treatment layers.

6. The printed circuit board of claim 1, further comprising:
a circuit pattern disposed on another surface of the first insulating layer.

7. The printed circuit board of claim 6, further comprising:
a via penetrating through the first insulating layer and connecting the circuit pattern to the first pad.

8. A printed circuit board, comprising:
a first insulating layer;
a first pad embedded in one surface side of the first insulating layer and having one surface exposed from one surface of the first insulating layer; and
a second pad embedded in the one surface side of the first insulating layer and having one surface exposed from the one surface of the first insulating layer,
wherein the one surface of the second pad and the one surface of the first insulating layer have a step difference therebetween.

9. The printed circuit board of claim 8, wherein the one surface of the first pad is substantially coplanar with the one surface of the first insulating layer.

10. The printed circuit board of claim 8,
wherein the one surface of the first pad and the one surface of the first insulating layer have a step difference therebetween,
wherein the one surface of the second pad and the one surface of the first insulating layer have a step difference therebetween, and
wherein a step difference between the one surface of the first pad and the one surface of the first insulating layer is smaller than a step difference between the one surface of the second pad and the one surface of the first insulating layer.

11. The printed circuit board of claim 8, further comprising:
a first surface treatment layer disposed on the exposed one surface of the first pad; and
a second surface treatment layer disposed on the exposed one surface of the second pad.

12. The printed circuit board of claim 11, wherein one surface of the second pad opposing a boundary between the second pad and the second surface treatment layer and the one surface of the first insulating layer have a step difference therebetween.

13. The printed circuit board of claim 11, wherein the first surface treatment layer and the second surface treatment layer are made of different materials.

14. The printed circuit board of claim 13,
wherein the first surface treatment layer includes at least one of gold (Au) and nickel (Ni), and
wherein the second surface treatment layer includes an organic compound.

15. A printed circuit board, comprising:
an insulating layer;
a pad embedded in the insulating layer, and having one surface exposed from one surface of the insulating layer and substantially coplanar with the one surface of the insulating layer; and
a first solder resist layer disposed on the one surface of the insulating layer, and having an opening exposing a region of the insulating layer where the pad is embedded.

16. The printed circuit board of claim 15, further comprising:
a circuit pattern disposed on another surface of the insulating layer.

17. The printed circuit board of claim 16, further comprising:
a via penetrating through the insulating layer and connecting the circuit pattern to the pad.

18. The printed circuit board of claim 17, wherein the via is tapered in a direction from the circuit pattern to the pad.

19. The printed circuit board of claim 16, further comprising:
a second solder resist layer disposed on another surface of the insulating layer, and having an opening exposing the circuit pattern.

20. The printed circuit board of claim 19, wherein the first solder resist layer is spaced apart from the pad, and
the second solder resist layer is in contact with the circuit pattern.
